(19) United States
(12) Patent Application Publication
(10) Pub. No.: US 2026/0246540 A1
(43) Pub. Date: Aug. 20, 2026

(54) TESTING RF SIGNAL CONTENT AND POWER

(71) Applicant: Teradyne, Inc., North Reading, MA (US)

(72) Inventors: Christopher D. Hinkle, Sudbury, MA (US); Robert E. Messier, South Burlington, VT (US); Rodrigo Carrillo-Ramirez, Chelmsford, MA (US)

(73) Assignee: Teradyne, Inc., North Reading, MA (US)

(21) Appl. No.: 19/054,299

(22) Filed: Feb. 14, 2025

(51) Int. Cl. H04B 17/00; G01R 31/26; G01R 31/28; H04B 17/391

(52) U.S. Cl. CPC H04B 17/0087; G01R 31/2628; G01R 31/2822; H04B 17/3912

(57) ABSTRACT

An example apparatus includes a power detector that is connectable to an output port of a device under test (DUT) to receive a first radio frequency (RF) signal or a first part of the first RF signal from the DUT. The power detector is configured to detect a power of the first RF signal or of the first part of the first RF signal. The apparatus includes an attenuator that is connectable to the outport port of the DUT and connectable to or connected to an input port of the DUT. The attenuator is configured to receive a second RF signal or a second part of the first RF signal from the DUT and to attenuate the second RF signal or the second part of the first RF signal to produce an attenuated RF signal for output to the input port of the DUT.

### TECHNICAL FIELD

This specification describes example implementations of systems and processes for testing radio frequency (RF) signal content and power.

### BACKGROUND

A test system is configured to test the operation of a device. A device tested by a test system is referred to as a device under test (DUT). A DUT may be configured to transmit wireless signals, such as radio frequency (RF) signals. The test system may test content and parameters of an RF signal as part of a process for testing the DUT.

### SUMMARY

An example apparatus includes a power detector that is connectable to an output port of a device under test (DUT) to receive a first radio frequency (RF) signal or a first part of the first RF signal from the DUT. The power detector is configured to detect a power of the first RF signal or of the first part of the first RF signal. The apparatus includes an attenuator that is connectable to the outport port of the DUT and connectable to or connected to an input port of the DUT. The attenuator is configured to receive a second RF signal or a second part of the first RF signal from the DUT and to attenuate the second RF signal or the second part of the first RF signal to produce an attenuated RF signal for output to the input port of the DUT. The apparatus may include one or more of the following features either alone or in combination.

The attenuator may be or include a variable attenuator that is controllable to add different amounts of attenuation to the second RF signal or the second part of the first RF signal. An amount of attenuation added to the second RF signal or the second part of the first RF signal may simulate a communication channel over which RF signals from the DUT are expected to travel during operation of the DUT. The attenuator may be or include a digital step attenuator to add the different amounts of attenuation to the second RF signal or the second part of the first RF signal.

The apparatus may include a switch between the output port of the DUT and both of the power detector and the attenuator. The switch may be controllable to create an electrical connection between (i) the output port of the DUT and the power detector or (ii) between the output port of the DUT and the attenuator. When the switch is configured to create the electrical connection between the output port of the DUT and the power detector, the attenuator may be configured to attenuate the second RF signal or the second part of the first RF signal so as to prevent or to limit transmission of the second RF signal or the second part of the first RF signal to the DUT.

The switch may be a first switch. The apparatus may include an impedance device connected to ground and a second switch between the input port of the DUT and both of the attenuator and the impedance device. The second switch may be controllable to create an electrical connection (i) between the input port of the DUT and the attenuator or (ii) between the input port of the DUT and the impedance device.

When the first switch is configured to create the electrical connection between the output port of the DUT and the power detector, the second switch may be configured to create the electrical connection between the input port of the DUT and the impedance device. When the first switch is configured to create the electrical connection between the output port of the DUT and the attenuator, the second switch may be configured to create the electrical connection between the input port of the DUT and the attenuator.

A controller may be configured to control the attenuator and the switch, or to control the attenuator, the first switch and the second switch. The controller may be configured to control the attenuator and the switch, or the attenuator, the first switch, and the second switch, based on the power of the first RF signal or the power of the first part of the first RF signal detected by the power detector.

The controller may be configured to determine if, or to obtain information that, the power of the first RF signal or the power of the first part of the first RF signal is within an acceptable range and, if the power of the first RF signal or the power of the first part of the first RF signal is within the acceptable range, the controller may be configured to control the switch to create the electrical connection between the output port of the DUT and the attenuator, and to control the attenuator to provide an amount of attenuation to the second RF signal or to the second part of the first RF signal.

The controller may be configured to determine if, or to obtain information that, the power of the first RF signal or the power of the first part of the first RF signal is within an acceptable range and, if the power of the first RF signal or the power of the first part of the first RF signal is within the acceptable range, the controller may be configured to control the first switch to create the electrical connection between the output port of the DUT and the attenuator, to control the second switch to create the electrical connection between the input port of the DUT and the attenuator, and to control the attenuator to provide an amount of attenuation to the second RF signal or to the second part of the first RF signal.

The apparatus may include memory storing calibration data associated with at least one of frequency or temperature and a temperature sensor to detect a temperature during operation of the DUT. The controller may be configured to select calibration data based on at least one of a frequency of the second RF signal, a frequency of the second part of the first RF signal, or the temperature, and to control at least the attenuator based on the calibration data selected.

The apparatus may include memory storing calibration data associated with at least one of frequency or temperature and a temperature sensor to detect a temperature during operation of the DUT. The controller may be configured to select calibration data based on at least one of a frequency of the second RF signal, a frequency of the second part of the first RF signal, or the temperature, and to calibrate the power detected for the first RF signal or the power detected for the first part of the first RF signal based on the calibration data selected.

The controller may include at least one of the following: one or more processing devices, programmable logic, or solid state circuitry. At least one of the first RF signal or the second RF signal may each have a frequency with a range of 1 gigahertz (GHz) to 72 GHz. The attenuator may be configured to attenuate the second RF signal or the second part of the first RF signal by up to 60 decibels (dB). The power detector and the attenuator may be in a loopback configuration with the DUT.

An example test system may include the foregoing apparatus, with or without any of the additional features described above, and one or more test instruments configured to control the apparatus. The one or more test instruments may be configured (i) to provide first data to the DUT, with the first RF signal or the first part of the first RF signal containing the first data, (ii) obtain information from the DUT that is based on second data received by the DUT in the second RF signal or in the second part of the first RF signal, and (iii) and to determine whether the DUT passed or failed testing based the information. The information may include a bit error rate (BER). Whether the DUT passed or failed testing may be based on the BER.

An example test system includes a device interface board (DIB) containing a DUT and a module on the DIB. The module includes a power detector that is connectable to an output port of the DUT to receive a first RF signal or a first part of the first RF signal from the DUT. The power detector is configured to detect a power of the first RF signal or of the first part of the first RF signal. The module includes an attenuator that is connectable to or connected to the outport port of the DUT and to an input port of the DUT. The attenuator is configured to receive a second RF signal or a second part of the first RF signal from the DUT and to attenuate the second RF signal or the second part of the first RF signal to produce an attenuated RF signal for output to the input port of the DUT. The test system includes one or more test instruments configured to control operation of at least part of the module. The one or more test instruments are configured (i) to provide first data to the DUT, with the first RF signal or the first part of the first RF signal containing the first data, (ii) to obtain information from the DUT, such as a BER, that is based on second data received by the DUT in the second RF signal or in the second part of the first RF signal, and (iii) and to determine whether the DUT passed or failed testing based on the information such as the BER.

Any two or more of the features described in this specification, including in this summary section, may be combined to form implementations not specifically described in this specification.

At least part of the devices, systems, circuitry, and processes described in this specification may be configured or controlled by executing, on one or more processing devices, instructions that are stored on one or more non-transitory machine-readable storage media. Examples of non-transitory machine-readable storage media include read-only memory, an optical disk drive, memory disk drive, and random access memory. At least part of the devices, systems, circuitry, and processes described in this specification may be configured or controlled using a computing system comprised of one or more processing devices and memory storing instructions that are executable by the one or more processing devices to perform various control operations. The devices, systems, circuitry, and processes described in this specification may be configured, for example, through design, construction, composition, arrangement, placement, programming, operation, activation, deactivation, and/or control.

The details of one or more implementations are set forth in the accompanying drawings and the following description. Other features and advantages will be apparent from the description and drawings, and from the claims.

### DESCRIPTION OF THE DRAWINGS

FIG. 1 is a block diagram of an example module configured for use in testing device radio frequency (RF) signal content and power.

FIG. 2 is a block diagram showing an example implementation of the module of FIG. 1 incorporated into a test system.

FIG. 3 is a block diagram showing an example implementation of components of the test system shown in FIG. 2.

FIG. 4 is a flowchart showing example operations included in an example process for testing device RF signal content and power.

Like reference numerals in different figures indicate like elements.

### DETAILED DESCRIPTION

Described herein are examples of systems and processes for testing an electronic device, referred to herein as a device under test (DUT). The DUT may be any type of electronic device such as, but not limited to, a radio frequency (RF) transceiver configured to implement wireless communications such as cellular, WiFi, WiGig (wireless gigabit), ultrawideband (UWB), and/or Bluetooth functionality.

The testing includes RF testing of the DUT. The RF testing may include testing content transmitted in RF signals output by the DUT and one or more parameters of the RF signals. For example, the testing may include testing the power of the RF signals transmitted by the DUT. The testing may include performing bit error rate (BER) testing on data transmitted by the RF signals. In an example, BER testing is performed by connecting the DUT to a test module in a loop-back configuration and determining whether the data transmitted by the DUT over a communication channel or simulated communication channel is the same as the data received by the DUT. A communication channel or simulated communication channel may include a frequency band over which the RF signals are transmitted to and from the DUT.

In some implementations, the RF signals tested by the example systems and processes described herein may have frequencies in a range of 1 gigahertz (GHz) to 72 GHz. However, RF signals having frequencies less than these or greater than these may also be tested using the example systems and processes. For example in some implementations, at least some of the RF signals tested by the example systems and processes may be in the millimeter wave (mmwave) range, which may include frequencies up to 300 GHz or frequencies between 30 GHz and 300 GHz.

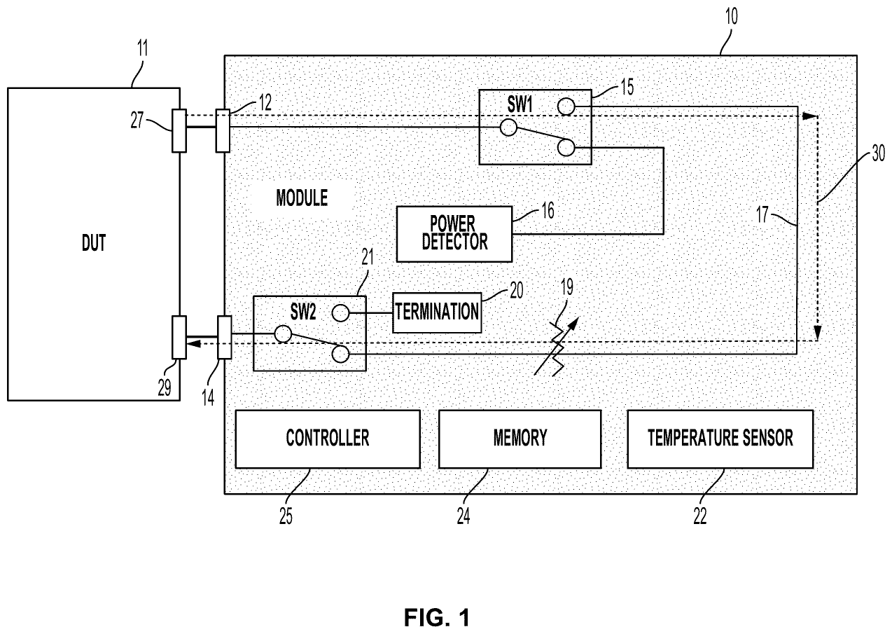

FIG. 1 is a block diagram showing an example implementation of a module 10 configured to test the power or an RF signal and to connect to a DUT 11 in a loop-back configuration to enable the DUT to test itself in some implementations. In this regard, an example loop-back configuration includes module 10 receiving an output RF signal from DUT 11 and electrically connecting that output RF signal to an input of the DUT to enable the DUT to make determinations based on the RF signal such as whether the data or stimulus expected to be output from the DUT in the RF signal is actually the data or stimulus received from the RF signal through the loop-back configuration.

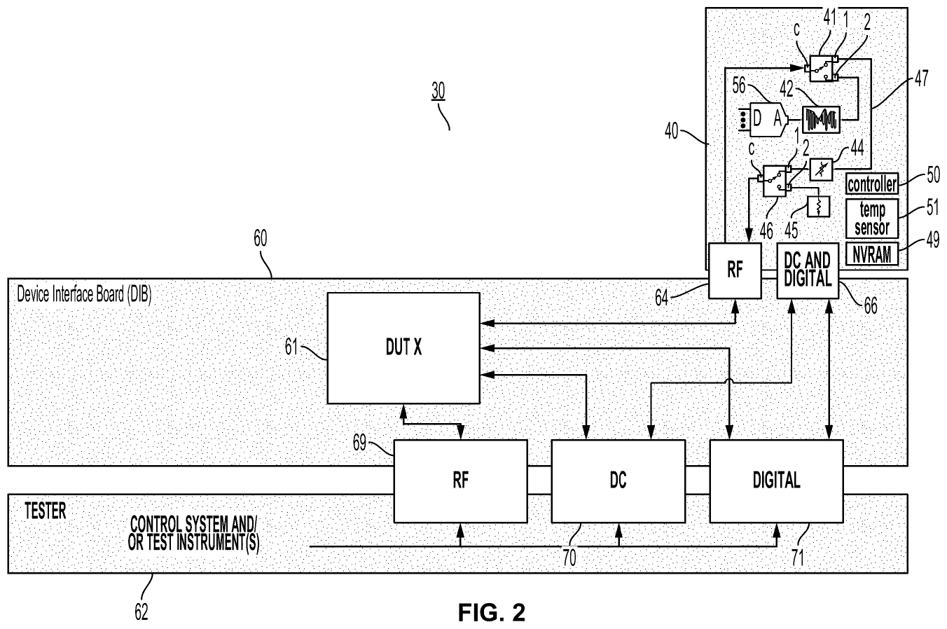

In this example, module 10 includes the following components, which are electrically connected or connectable as shown in FIG. 1: input port 12, output port 14, a first switch 15 (SW1), a power detector 16, a simulated communication channel 17 containing an attenuator 19, a termination circuit 20, a second switch 21 (SW2), a temperature sensor 22, memory 24, and a controller 25 which may be or include an interface to an external controller such as those described below. In some implementations, second switch 21 (SW2) and termination circuit 20 are omitted, as described below. In the example of FIG. 1, input port 12 is electrically connected to output port 27 of DUT 11 and output port 14 is electrically connected to input port 29 of DUT 11. In some examples, the DIB or a portion thereof is between the DUT and the module (see FIG. 2). Electrical connections between the DUT and the module may be made using wired or wireless media, as described below.

As shown in FIG. 1, first switch 15 is electrically connected between an input port 12 of module 10 and both of power detector 16 and attenuator 19 on simulated communication channel 17. First switch 15 is controllable to create an electrical connection (i) between input port 12 (and thus the output port 27 of DUT 11) and power detector 16, or (ii) between input port 12 (and thus the output port 27 of DUT 11) and variable attenuator 19. In some implementations, first switch 15 may be implemented using solid state electronics or a microelectromechanical (MEMS) device. First switch 15 may be configured, e.g., operated by control by a control system, a test system, or a test instrument in the test system, as described below.

Power detector 16 is configured to operate when switch 15 is controlled to create an electrical connection between the output port 27 of DUT 11 and power detector 16. In particular, when the electrical connection to DUT 11 is made, power detector 16 is configured to receive, from DUT 11, a first radio frequency (RF) signal or a first part of the first RF signal, and to detect a power of the first RF signal or of the first part of the first RF signal. In some implementations, power detector 16 and additional circuitry included therein or therewith may also be configured to detect the frequency of the signal(s) received. Power detector 16 may be configured to report the detected power and, in some examples, the frequency to a local controller 25, a control system, a test system, or a test instrument in the test system, as described below.

In some implementations, power detector 16 is configured to translate the RF signal power into a direct current (DC) voltage and to report that DC voltage as an indication of the signal power. Examples of circuits that may implement the power detector include, but are not limited to, a Schottky diode configured to measure a power of an RF signal by converting the RF power into a proportional direct current (DC) voltage; a peak detector configured to measure a maximum signal amplitude, a root mean square (RMS) detector configured to determine the average power of an RF signal, and/or a logarithmic detector configured to provide a logarithmic output that is proportional to the input power level of an RF signal.

In the foregoing description, power detector 16 is said to receive “a first RF signal or a first part of the first RF signal”. Power detector 16 is said to receive the first RF signal if DUT 11 stops transmitting an RF signal (a first RF signal) following power detection and starts transmitting another (second) RF signal after first switch 15 is reconfigured to connect module 10 in the loop-back configuration as described below. Power detector 16 is said to receive the first part of the first RF signal if DUT 11 does not stop transmitting an RF signal following power detection such that RF signal transmission continues while first switch 15 is reconfigured to connect module 10 in the loop-back configuration. In this latter case, the first part of the RF signal is detected by the power detector and the second part of the RF signal is provided back to the DUT via the simulated communication channel 17. Whether the DUT stops transmitting while first switch 15 is reconfigured may be dictated by a test program that controls testing of DUT 11. Test programs are described in more detail below.

Simulated communication channel 17 includes one or more electrical conduits and/or transmission lines configured-for example designed, connected, and/or arranged-to transmit RF signals, examples of which include, but are not limited to, one or more coaxial cable(s), one or more waveguide(s), and/or one or more printed circuit board (PCB) conductive trace(s). Simulated communication channel 17 includes an attenuator 19, which may be a variable attenuator, that is electrically connectable to input port 12 (and thus to outport port 27 of DUT 11) and that is electrically connectable to output port 14 (and thus to input port 29 of DUT 11) through operation of switches 15 and 21, respectively. In this configuration, attenuator 19 is configured to receive a second RF signal or a second part of the first RF signal from the DUT and to attenuate the second RF signal or the second part of the first RF signal to produce an attenuated RF signal for output to input port 29 of the DUT 11.

In some implementations, attenuator 19 is a variable attenuator that is controllable to add different amounts of attenuation to the RF signal that is provided to the DUT. Attenuation includes the loss of signal strength or signal power, for example. This loss of signal strength may be a result of insertion loss, which may include the amount of signal power that is lost when a device is inserted into a transmission line.

In some implementations, an amount of attenuation added to the RF signal that is provided to the DUT simulates insertion loss that a DUT would expect to experience when connected to a transmission line (e.g., a communication channel). In some implementations, an amount of attenuation added to the RF signal that is provided to the DUT simulates attenuation that would occur over a communication channel over which RF signals from the DUT are expected to travel during operation of the DUT. In some implementations, different amounts of attenuation may be added to the RF signal that is provided to the DUT to simulate different attenuations that may occur under different circumstances. For example, attenuation may be added to simulate both insertion loss and signal loss over a lengthy transmission line.

In some implementations, attenuator 19 is or includes a digital step attenuator to add the different amounts of attenuation to the RF signal that is provided to the DUT. A digital step attenuator may be configured to switch into the simulated communication channel discrete amounts of attenuation using semiconductor devices such as pin diodes or transistors or using MEMs devices or the like. Attenuator 19 may be controlled to provide different amounts of attenuation by a control system, a test system, or a test instrument in the test system, as described below. For example, a test program executing on a control system, a test system, or a test instrument in the test system may specify the amount(s) of attenuator that attenuator 19 is to provide and the time(s) or other circumstances when that attenuation is to be provided.

In some implementations, attenuator 19 is configured to attenuate the RF signals by up to 60 decibels (dB). In some implementations, the attenuator is configured to attenuate the RF signals by up to 30 db. In some implementations, the attenuator may be configured to add attenuation in step sizes of 1 dB or less (e.g., 0.5 dB) to achieve a maximum attenuation or a predefined attenuation. Attenuator may be is configured to attenuate the RF signals at other amounts not listed here.

Second switch 21 is between output port 14 (and thus input port 29 of DUT 11) and both of attenuator 19 (on simulated communication channel 17) and termination circuit 20. Second switch 21 is controllable to create an electrical connection (i) between output port 14 (and thus input port 29 of DUT 11) and attenuator 19 on communication channel 17 or (ii) between output port 14 (and thus input port 29 of DUT 11) and termination circuit 20. Second switch 21 may be configured through control by a control system, a test system, or a test instrument in the test system, as described below. In some implementations, second switch 21 and termination circuit 20 may be omitted from module 10, as described below.

In some implementations, when first switch 15 is configured to create the electrical connection between output port 27 of the DUT and attenuator 19, second switch 21 is configured to create the electrical connection between input port 29 of the DUT and attenuator 19. In this configuration, illustrated by arrows 30, module connects to DUT 11 in a loop-back configuration such that RF signal(s) output to module 10 pass from the output port 27 of DUT 11, through module 10 where those RF signal(s) may be subjected to attenuation, and then into the input port 29 of DUT 11.

In some implementations, when first switch 15 is configured to create the electrical connection between the output port 27 of the DUT and power detector 16, second switch 21 is configured to create the electrical connection between input port 29 of the DUT and termination circuit 20. This may be done so that, during power detection, RF signal does not inadvertently pass through the simulated communication, which may result in inaccurate readings by the power detector.

In some implementations, when first switch 15 is configured to create the electrical connection between the output port 27 of the DUT and power detector 16, attenuator 19 may be set to maximum attenuation-for example, to mimic an open circuit along simulated transmission line 17-effectively preventing RF signal or all but a very small part of the RF signal from passing to input 29 of the DUT. In these example implementations, simulated transmission line 17 may be directly connected to output port 14 and second switch 21 and termination circuit 20 may be omitted from the circuitry. In these examples, attenuator may be controlled using as described herein.

In some implementations, termination circuit 20 may be or include one or more impedance devices connected to electrical ground. For example, termination circuit 20 may be a 50Ω, 100Ω, or 200Ω resistor or resistor network connected to, that is terminating in, electrical ground.

In some implementations, controller 25 may reside on module 10. In this case, controller 25 may be referred to as a “local controller”. In some implementations, controller 25 may be external to module 10 and there may be an interface to controller on module 10. In some implementations, control functionality may be implemented using one or more local controllers 25 that reside on module 10 and one or more external controllers that are, or are part of, an external control system, a test system, and/or a test instrument in the test system, as described below. References to a “controller” below are intended to cover all of these potential contingencies.

The controller may be, or include, one or more of the following: one or more processing devices such as one or more microprocessors, programmable logic such as a field programmable gate array (FPGA), one or more application-specific integrated circuits (ASICs), and/or solid state circuitry. The controller may be configured-for example programmed or designed-to control at least one of attenuator 19, first switch 15, or second switch 21 as described in the preceding examples. In some implementations, the controller is configured to control the attenuator, the first switch, and the second switch based on the power of the first RF signal or the power of the first part of the first RF signal detected by power detector 16. In implementations where the second switch is omitted, the controller is configured to control the attenuator and switch 15 based on the power of the first RF signal or the power of the first part of the first RF signal detected by power detector 16.

In some implementations, the controller is configured to determine if, or to obtain information that, the power of the first RF signal or the power of the first part of the first RF signal detected by power detector 16 is within an acceptable range. For example, the controller may receive the detected power from the power detector and compare the detected power to a predefined range, which may be programmed into the controller beforehand. The predefined range may be an acceptable range of signal power defined for operation of the DUT. For example, if the RF signal power is within that range, then the DUT is considered to be operating acceptably and, therefore, will pass testing at least with respect to signal power. If the RF signal power is outside that range, then the DUT is considered not to be operating acceptably (e.g., the signal power is too low) and, therefore, will fail testing at least with respect to signal power.

In some implementations, if the power of the RF signal from the DUT is within the acceptable range, the controller is configured to control first switch 15 to create the electrical connection between the output port 27 of the DUT and attenuator 19, to control second switch 21 to create the electrical connection between input port 29 of the DUT and attenuator 19, and to control attenuator 19 to provide an amount of attenuation to the second RF signal or to the second part of the first RF signal. If second switch 21 is omitted, the controller is configured to control first switch 15 to create the electrical connection between the output port 27 of the DUT and attenuator 19 and to change the amount of attenuation provided by attenuator from the maximum to the amount used to simulate a transmission line. In other words, if the RF signal passes testing with respect to signal power (for example, the RF signal has an acceptable power level), then module 10 may be connected in the loop-back configuration to enable testing of the content of the RF signal, such as BER testing. On the other hand, if the RF signals fails testing with respect to signal power, the controller may not proceed to connect module 10 in the loop-back configuration and, therefore, may not proceed to test the content of the RF signal. In such examples, if the RF signal fails testing with respect to signal power, the DUT may be marked as having failed testing and there may be no need to proceed with further testing, including testing the content of the RF signal.

Module 10 may include a temperature sensor 22 to detect a temperature during operation of the DUT. Examples of temperature sensors that may be used include, but are not limited to, negative temperature coefficient (NTC) thermistors, resistance temperature detectors (RTDs), thermocouples, and/or semiconductor-based integrated (IC) sensors. The detected temperature may be used to select calibration coefficients to control operation of the module, including the attenuator based on temperature.

In this regard, memory 24 may store calibration data (e.g., calibration coefficients or other information) associated with at least one of frequency or temperature. For example, calibration data may be associated with temperature only, with frequency only, or with both frequency and temperature. The calibration data may be determined beforehand and stored in memory. For example, the amount of attenuation may vary based on temperature and/or frequency of the RF signals. That is, attenuator 19 may provide more or less than the amount of attenuation that it is expected to provide (e.g., programmed to provide) at different signal frequencies and temperatures. In another example, the power detected by power detector 16 may vary based on temperature and/or frequency of the RF signals. For example, power detector 16 may read more or less than the actual signal power at different temperatures and/or different frequencies. The calibration data may be used to compensate for, e.g., counteract, the effects of temperature and/or signal frequency on deviations from expected power detection and attenuation produced.

The controller may be configured to select calibration data from memory 24 based on at least a frequency of the RF signal determined by the power detector and circuitry associated therewith and calibrate (e.g., increase or decrease) the power reported by the power detector using that calibration data. The controller may be configured to select calibration data from memory 24 based on at least the temperature detected by the temperature sensor and calibrate the power reported by the power detector using that calibration data. The controller may be configured to select calibration data from memory 24 based on both the temperature detected by the temperature sensor and the frequency of the RF signal determined by the power detector and calibrate the power reported by the power detector using that calibration data. The controller may be configured to select calibration data from memory 24 based on at least a frequency of the RF signal determined by the power detector and calibrate (e.g., increase or decrease) the attenuation provided by attenuator 19 using that calibration data. The controller may be configured to select calibration data from memory 24 based on at least the temperature detected by the temperature sensor and calibrate the attenuation provided by attenuator 19 using that calibration data. The controller may be configured to select calibration data from memory 24 based on both the temperature detected by the temperature sensor and the frequency of the RF signal determined by the power detector and calibrate the attenuation provided by attenuator 19 using that calibration data.

FIG. 2 shows an example implementation of module 40 that is part of a test system 30. Referring also to FIG. 1, in this implementation, switch 41 is an implementation of switch 15, power detector 42 is an implementation of power detector 16, attenuator 44 is an implementation of attenuator 19, termination circuit 45 is an implementation of termination circuit 20, switch 46 is an implementation of switch 21, simulated transmission line 47 is an implementation of simulated transmission line 17, NVRAM (non-volatile random access memory) 49 is an implementation of memory 24, controller 50 is an implementation of controller 25, and temperature sensor 51 is an implementation of temperature sensor 22. The counterpart components may have similar or identical structures and functions. As explained above, in some implementations, the second switch and termination circuit may be omitted.

Module 40 includes an analog-to-digital (A/D) converter 56 which receives an analog (e.g., DC) signal from power detector 42 representing the power of the received RF signal and converts that analog signal to a digital signal for output to the controller which, as explained herein, may be or include the local controller 50, an external control system, and/or one or more test instruments of a test system.

FIG. 2 also shows a device interface board (DIB) 60. DIB 60 may be a printed circuit board (PCB) or other structure on which DUT 61 may be mounted for testing. Module 40 may also be mounted on the DIB or otherwise electrically and communicatively coupled to the DIB. Communications between module 40 and DUT 61, including transmission of RF signals, may pass through the DIB (e.g., over coaxial cables, coaxial constructs, PCB traces, or waveguides in the DIB) or those communications may be external to the DIB (e.g., wireless). Power, including voltage, may be run via one or more layers in the DIB to DUTs and modules connected to the DIB. DIB 60 may include one or more ground layers and one or signal layers with connected vias for transmitting signals to-and-from the DUTs and/or to-and-from the modules.

In this example, RF interface 64, e.g., coaxial cable, waveguides, and/or circuit interfaces therefor, connects module 40 to DIB 60 to enable DIB 60 to transmit RF signals from DUT 61 to module 40 and to transmit RF signals from module 40 to DUT 61. In some implementations, the RF signals to-and-from the module and to-and-from the DUT may be transmitted wirelessly, e.g., over the air. DC and digital interface 66 connects module 40 to DIB 60 to transmit control signals from tester 62 to module 40 and to receive data (e.g., power levels or temperature) at tester 62 from module 40.

FIG. 2 also shows tester 62, such as automatic test equipment (ATE) 62. Tester 62 may be configured, as described below, to control testing of DUT 61. RF interface 69 connects DIB 60 to tester 62 to enable RF communication between DIB 60 and tester 62. RF communication may include signals sent between DUT 61 and tester 62. DC interface 70 connects DIB 60 to tester 62 to enable DC signals to be sent between DIB 60 and tester 62. DC signals may be sent between tester 62 and DUT 61 or between tester 62 and module 40. Digital interface 71 connects DIB 60 to tester 62 to enable digital signals to be sent between DIB 60 and tester 62. Digital signals may be sent between tester 62 and DUT 61 or between tester 62 and module 40. In this example, DC and digital signals such as detected power and temperature and control signals may be transmitted directly between tester 61 and module 40 via DIB 60. In this example, DC and digital signals, such as test signals and control signals, may be transmitted directly between tester 61 and DUT 61 via DIB 60. Other implementations may enable signals to be routed differently than as shown in FIG. 2.

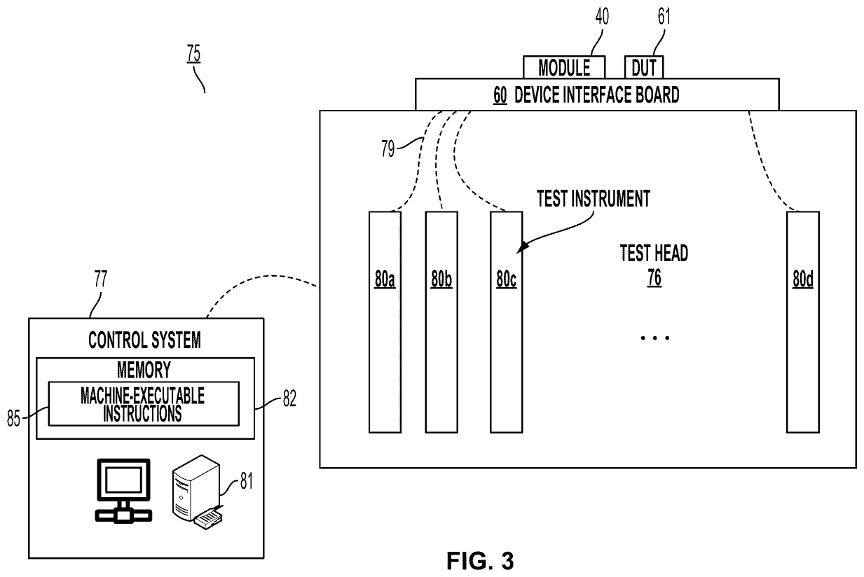

FIG. 3 shows components of example automatic test equipment (ATE) 75 that may be an example implementation of, or include components of, tester 62 of FIG. 2. ATE 76 includes a test head 76, DIB 60, and an external control system 77, which may be a control system, or portion thereof, that is external to the test head or module.

DIB 60 is connected to test head 76 and includes mechanical and electrical interfaces to one or more DUTs, such as DUT 61, that are being tested or are to be tested by the ATE. DIB 60 also contains, or is connected to a module, such as module 40 (or module 10 of FIG. 1) for operation with the DUTs thereon. In some implementations, there may be one module on the DIB, such as module 40, for each corresponding DUT. In some implementations, a module on the DIB, such as module 40, may service multiple DUTs. For example, RF signals may be multiplexed from a DUT to a module and from the module to the DUT. The control system may control operation of one or more multiplexers located between the module and DUTs to route signals between the module and DUTs.

Test signals and response signals, such as RF signals, and other signals such as signals representing amounts of power detected by power detector 41 and temperature detected by temperature sensor 51, may pass over test channels among the DUTs, the modules, and/or the test instruments described below. Examples of the test channels may include coaxial cables, waveguide, and shielded twisted pair wires.

Control system 77 may communicate with components included in the test head to control testing. For example, control system 77 may download test program sets to test instruments 80a, 80b, 80c, and 80d in the test head. In an example, a test program generates a test pattern (or flow) to provide signals to the DUT for testing and/or to control the DUT to output RF signals to the modules. The test pattern may be written to output test signals to elicit a response from the DUT. For example, the test pattern may instruct a DUT: to output an RF signal to module 40, to receive an RF signal from module 40, and to perform a test such as a BER test based on an extent to which the data in the RF signal received from the module resembles the data output in the RF signal by the DUT, and to report the results of the test to a test instrument or control system, which may evaluate the test results (e.g., the BER) to determine if the DUT passed or failed testing. For example, in the case of BER testing, if the BER is below a predefined threshold, the DUT may pass testing whereas if the BER is above the predefined threshold, the DUT may fail testing.

The test instruments include hardware devices, each of which may include one or more processing devices, pin electronics, programmable logic such as an FPGA, and memory. Test instruments 80a to 80d may execute the test programs to test DUTs held on the DIB, which testing includes, but is not limited to, controlling the modules on the DIB, including the switches contained on the modules and the variable attenuator, to implement the power and RF testing described with respect to FIGS. 1, 2, and 4. Control system 77 may also send, to test instruments in the test head, instructions, test data, and/or other information that is usable by the test instruments to control the modules on the DIB, including the switches contained thereon and the variable attenuator, to implement the power and RF testing described with respect to FIGS. 1, 2, and 4. In some implementations, this information may be sent via a computer or other type of network or via a direct electrical path. In some implementations, this information may be sent via a local area network (LAN) or a wide area network (WAN).

Test instruments 80a to 80d may each be connected to respective test channels 79 to communicate over DIB 60 to perform one or more of DUT testing and/or other functions described herein. Although only four test instruments are shown, the ATE 75 may include any number of test instruments, including those residing outside of test head 76. Signals, including RF, DC and digital signals, may be sent to, and received from, the DUT over multiple test channels or other electrically conductive media.

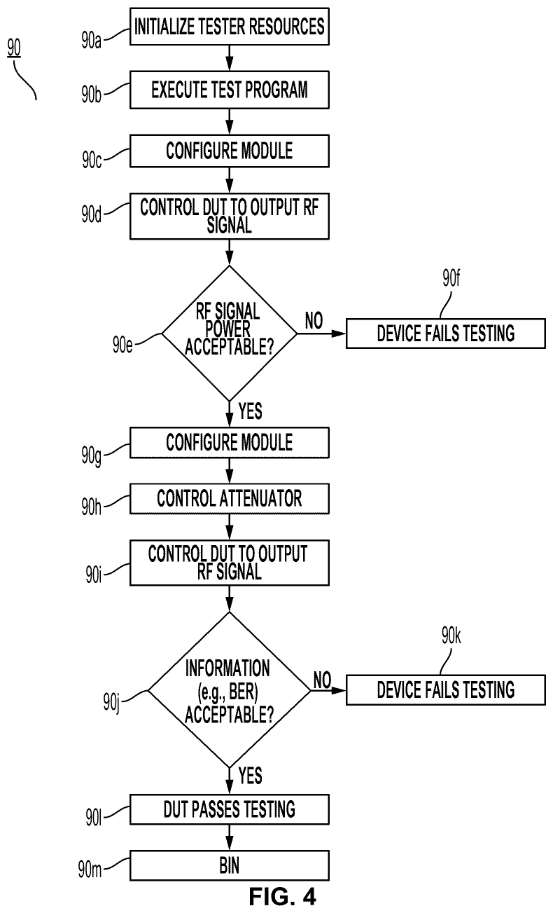

Control system 77 may contain one or more processing devices 81 and memory 82 storing instructions that are executable. The one or more processing devices 81 may execute instructions 85 to control, or to implement at least part of, process 90 of FIG. 4 in conjunction with module 40 and/or one or more of a test instrument 80a to 80d or a component of the test instrument such as an FPGA.

In some implementations, at least part of the control functionality of control system 77 may be on module 40. In some implementations, all or part of the control functionality attributed to control system 77 may also or instead be implemented on a test instrument and/or all or part of the testing functionality attributed to one or more test instruments may also or instead be implemented on control system 77. In some implementations, at least part of the control functionality may be distributed across processing device(s) 81, one or more of test instruments 80a to 80d, and/or module 40.

FIG. 4 is a flowchart showing operations that may be included in an example process 90 for testing RF signal content and power. Process 90 may be implemented, at least in part, based on one or more test programs executing on control system 77 and/or test instruments 80a to 80d. Operations on module 40 that are instructed by the one or more test programs may be routed through controller 50 on module 40.

Process 90 includes initializing (90a) tester resources and executing (90b) a test program to test signal content and power of an RF signal output by a DUT.

Process 90 includes configuring (90c) module 40 to test the power of signal(s) output by the DUT to the module. The configuration process may include configuring first switch 41 to create the electrical connection between the output port of DUT 61 and power detector 42 and configuring second switch 46 to create the electrical connection between the input port of DUT 61 and the termination circuit 45. The configuration process may include configuring first switch 41 to create the electrical connection between the output port of DUT 61 and power detector 42 and configuring the attenuator to provide maximum attenuation or attenuation to simulate an open circuit or close to an open circuit e.g., less than 5%, less than 4%, less than 3%, less than 2%, or less than 1% of the RF signal passing through the attenuator to the DUT.

Process 90 controls (90d) the DUT to output an RF signal from the DUT's output port to an input port of module 40. Module 40 receives the RF signal and, by virtue of its configuration in operation 90c, routes the RF signal to power detector 42.

Power detector 42 detects the RF signal and outputs information (e.g., DC signals or digital data) representing the power of the RF signal. In some implementations, controller 50 may calibrate this information prior to outputting the power to the control system 77 and/or test instruments 80a to 80d. For example, controller 50 may receive the information representing the power of the RF signal and may also receive the frequency of the RF signal from the power detector and the module temperature from the temperature sensor. Controller 50 may use the frequency and temperature to obtain calibration data to calibrate the information representing the power of the RF signal. For example, controller may retrieve calibration information from NVRAM 49 that is for the received frequency and temperature. The controller calibrates the information representing the power of the RF signal to produce calibrated information and outputs the calibrated information to control system 77 and/or test instruments 80a to 80d. Control system 77 and/or test instruments 80a to 80d determine (90e), based on the calibrated information, whether the RF signal power is within an acceptable range, e.g., above a predefined threshold.

If the RF signal power is within the acceptable range, testing proceeds to the content testing portion of process 90. If the RF signal power is not within the acceptable range, the DUT is deemed to fail (90f) testing. In this case, in some implementations, no further testing on the DUT is performed.

Assuming that the DUT passed testing, Process 90 includes configuring (90g) module 40 to test the content of signal(s) output by the DUT to the module. This configuration process may include configuring first switch 41 to create the electrical connection between the output port of the DUT and attenuator 44 and, in implementations that include a second switch configuring second switch 46 to create the electrical connection between the input port of the DUT and the attenuator 44. This configuration is the loop-back configuration in which an RF signal output by the DUT is attenuated by module 40 and the resulting attenuated signal provided back to the DUT, which may be configured to analyze the signal. In implementations where the second switch is omitted, this operation is omitted.

Process 90 includes controlling (90h) attenuator 44 to provide a level of attenuation dictated by the test program. In some implementations, controller 50 may calibrate this information prior to controlling attenuator to provide the level of attenuation. For example, controller 50 may receive the amount of attenuation from control system 77 and/or test instruments 80a to 80d and may also receive the frequency of the RF signal from the power detector and the module temperature from the temperature sensor. Controller 50 may use the frequency and temperature to obtain calibration data to calibrate the amount of attenuation to be provided by the attenuator. For example, the controller calibrates the amount of attenuation to produce a calibrated attenuation and uses that calibrated attenuation to set the amount of attenuation to be provided by attenuator 44.

Process 90 includes controlling (90i) the DUT to output an RF signal or to continue outputting an RF signal if RF signal transmission was never discontinued. The RF signal includes first data modulated into the signal. In the loop-back configuration, (i) the first data is provided from the DUT to module 40 as part of the RF signal, (ii) the RF signal or a portion thereof is attenuated in module 40 to produce an attenuated signal, (iii) second data in the attenuated signal is received by the DUT from module 40, and (iv) the DUT determines how much the second data resembles the first data. For example, if the attenuated RF signal is weak, the DUT may not be able to identify a sufficient amount of the data contained therein accurately. This may mean that the original RF signal is not strong enough to compensate for the attenuation provided and, as a result, the DUT may fail this portion of the testing.

In some implementations, the DUT may perform testing, such as BER testing, to determine information, such as a BER, resulting from RF signal transmission through module 40. The DUT may provide the information, such as the BER, to control system 77 and/or test instruments 80a to 80d. Control system 77 and/or test instruments 80a to 80d may receive the information, such as the BER, and compare (90j) the information, such as the BER, to a predefined level, which may be set by the test program or programmed into the test system. If the information, such as the BER, exceeds an acceptable level or does not reach a desired level, the DUT fails testing (90k). If the information, such as the BER, is at or below the acceptable level or reaches the desired level, the DUT passes testing (90l). Other types of testing may be performed in addition to BER testing, such as jitter measurements and signal quality analysis.

Operations 90a through 90l may be performed for multiple DUTs and modules on, or associated with, DIB 60. Process 90 may bin (90m) the DUT(s) based on whether they have passed or failed testing and, after all DUTs have been tested, shut-down the test system.

All or part of the systems and processes described herein including but not limited to process 90 and variants thereof may be configured and/or controlled at least in part by one or more processing devices using one or more computer programs tangibly embodied in one or more information carriers, such as in one or more non-transitory machine-readable storage media. A computer program can be written in any form of programming language, including compiled or interpreted languages, and it can be deployed in any form, including as a stand-alone program or as a module, part, subroutine, or other unit suitable for use in a computing environment. A computer program can be deployed to be executed on one computer or on multiple computers at one site or distributed across multiple sites and interconnected.

Actions associated with configuring or controlling the test system and processes described herein can be performed by one or more programmable processors executing one or more computer programs to control or to perform all or some of the operations described herein. All or part of the test systems and processes can be configured or controlled by special purpose logic circuitry, such as, an FPGA (field programmable gate array) and/or an ASIC (application-specific integrated circuit) or embedded microprocessor(s) localized to the instrument hardware.

Processors suitable for the execution of a computer program include, by way of example, both general and special purpose microprocessors, and any one or more processors of any kind of digital computer. Generally, a processor will receive instructions and data from a read-only storage area or a random access storage area or both. Elements of a computer include one or more processors for executing instructions and one or more storage area devices for storing instructions and data. Generally, a computer will also include, or be operatively coupled to receive data from, or transfer data to, or both, one or more machine-readable storage media, such as mass storage devices for storing data, such as magnetic, magneto-optical disks, or optical disks. Non-transitory machine-readable storage media suitable for embodying computer program instructions and data include all forms of non-volatile storage area, including by way of example, semiconductor storage area devices, such as EPROM (erasable programmable read-only memory), EEPROM (electrically erasable programmable read-only memory), and flash storage area devices; magnetic disks, such as internal hard disks or removable disks; magneto-optical disks; and CD-ROM (compact disc read-only memory) and DVD-ROM (digital versatile disc read-only memory).

As used herein, the terms “comprises,” “comprising,” “includes,” “including,” “has,” “having,” “contains,” “containing,” and any variations thereof, are intended to cover a non-exclusive inclusion, such that systems, techniques, apparatus, structures, processes, or other subject matter described or claimed herein that includes, has, or contains an element or list of elements does not include only those elements but can include other elements not expressly listed or inherent to such systems, techniques, apparatus, structures, processes or other subject matter described or claimed herein.

All examples described herein are non-limiting.

In the description and claims provided herein, the adjectives “first”, “second”, “third”, and the like do not designate priority or order unless context suggests otherwise. Instead, these adjectives may be used solely to differentiate the nouns that they modify.

Any mechanical or electrical connection herein may include a direct physical connection or an indirect physical connection that includes one or more intervening devices unless context suggests otherwise. A connection between two electrically conductive devices includes an electrical connection unless context suggests otherwise. The signals described herein are electrical signals unless context suggests otherwise.

Elements of different implementations described may be combined to form other implementations not specifically set forth previously. Elements may be left out of the systems described previously without adversely affecting their operation or the operation of the system in general. Furthermore, various separate elements may be combined into one or more individual elements to perform the functions described in this specification.

Other implementations not specifically described in this specification are also within the scope of the following claims.

What is claimed is:

1. An apparatus comprising:
a power detector that is connectable to an output port of a device under test (DUT) to receive a first radio frequency (RF) signal or a first part of the first RF signal from the DUT, the power detector to detect a power of the first RF signal or of the first part of the first RF signal; and
an attenuator that is connectable to the outport port of the DUT and connectable to or connected to an input port of the DUT, the attenuator to receive a second RF signal or a second part of the first RF signal from the DUT and to attenuate the second RF signal or the second part of the first RF signal to produce an attenuated RF signal for output to the input port of the DUT.

2. The apparatus of claim 1, wherein the attenuator comprises a variable attenuator that is controllable to add different amounts of attenuation to the second RF signal or the second part of the first RF signal.

3. The apparatus of claim 2, wherein an amount of attenuation added to the second RF signal or the second part of the first RF signal simulates a communication channel over which RF signals from the DUT are expected to travel during operation of the DUT.

4. The apparatus of claim 2, wherein the attenuator comprises a digital step attenuator to add the different amounts of attenuation to the second RF signal or the second part of the first RF signal.

5. The apparatus of claim 1, further comprising:
a switch between the output port of the DUT and both of the power detector and the attenuator, the switch being controllable to create an electrical connection between (i) the output port of the DUT and the power detector or (ii) between the output port of the DUT and the attenuator.

6. The apparatus of claim 1, wherein when the switch is configured to create the electrical connection between the output port of the DUT and the power detector, and the attenuator is configured to attenuate the second RF signal or the second part of the first RF signal so as to prevent or to limit transmission of the second RF signal or the second part of the first RF signal to the DUT.

7. The apparatus of claim 5, wherein the switch comprises a first switch and wherein the apparatus further comprises:
an impedance device connected to ground; and
a second switch between the input port of the DUT and both of the attenuator and the impedance device, the second switch being controllable to create an electrical connection (i) between the input port of the DUT and the attenuator or (ii) between the input port of the DUT and the impedance device.

8. The apparatus of claim 7, wherein when the first switch is configured to create the electrical connection between the output port of the DUT and the power detector, the second switch is configured to create the electrical connection between the input port of the DUT and the impedance device.

9. The apparatus of claim 7, wherein when the first switch is configured to create the electrical connection between the output port of the DUT and the attenuator, the second switch is configured to create the electrical connection between the input port of the DUT and the attenuator.

10. The apparatus of claim 5, further comprising:
a controller configured to control the attenuator and the switch.

11. The apparatus of claim 10, wherein the controller is configured to control the attenuator and the switch based on the power of the first RF signal or the power of the first part of the first RF signal detected by the power detector.

12. The apparatus of claim 9, further comprising:
a controller configured to control the first switch, the second switch, and the attenuator;
wherein the controller is configured to determine if, or to obtain information that, the power of the first RF signal or the power of the first part of the first RF signal is within an acceptable range and, if the power of the first RF signal or the power of the first part of the first RF signal is within the acceptable range, the controller is configured to control the first switch to create the electrical connection between the output port of the DUT and the attenuator, to control the second switch to create the electrical connection between the input port of the DUT and the attenuator, and to control the attenuator to provide an amount of attenuation to the second RF signal or to the second part of the first RF signal.

13. The apparatus of claim 10, further comprising:
memory storing calibration data associated with at least one of frequency or temperature; and
a temperature sensor to detect a temperature during operation of the DUT;
wherein the controller is configured to select calibration data based on at least one of a frequency of the second RF signal, a frequency of the second part of the first RF signal, or the temperature, and to control at least the attenuator based on the calibration data selected.

14. The apparatus of claim 10, further comprising:
memory storing calibration data associated with at least one of frequency or temperature; and
a temperature sensor to detect a temperature during operation of the DUT;
wherein the controller is configured to select calibration data based on at least one of a frequency of the second RF signal, a frequency of the second part of the first RF signal, or the temperature, and to calibrate the power detected for the first RF signal or the power detected for the first part of the first RF signal based on the calibration data selected.

15. The apparatus of claim 10, wherein the controller comprises at least one of the following: one or more processing devices, programmable logic, or solid state circuitry.

16. The apparatus of claim 1, wherein at least one of the first RF signal or the second RF signal each has a frequency with a range of 1 gigahertz (GHz) to 72 GHz.

17. The apparatus of claim 1, wherein the attenuator is configured to attenuate the second RF signal or the second part of the first RF signal by up to 60 decibels (dB).

18. The apparatus of claim 1, wherein the power detector and the attenuator are in a loopback configuration with the DUT.

19. A test system comprising:
the apparatus of claim 1; and
one or more test instruments configured to control the apparatus, the one or more test instruments being configured (i) to provide first data to the DUT, the first RF signal or the first part of the first RF signal containing the first data, (ii) obtain information from the DUT that is based on second data received by the DUT in the second RF signal or in the second part of the first RF signal, and (iii) and to determine whether the DUT passed or failed testing based the information.

20. The test system of claim 19, wherein the information comprises a bit error rate (BER), and wherein whether the DUT passed or failed testing is based on the BER.

21. A test system comprising:
a device interface board (DIB) containing a device under test (DUT);
a module on the DIB, the module comprising:
a power detector that is connectable to an output port of the DUT to receive a first radio frequency (RF) signal or a first part of the first RF signal from the DUT, the power detector to detect a power of the first RF signal or of the first part of the first RF signal; and
an attenuator that is connectable to the outport port of the DUT and connectable to or connected to an input port of the DUT, the attenuator to receive a second RF signal or a second part of the first RF signal from the DUT and to attenuate the second RF signal or the second part of the first RF signal to produce an attenuated RF signal for output to the input port of the DUT; and
one or more test instruments configured to control operation of at least part of the module, the one or more test instruments being configured (i) to provide first data to the DUT, the first RF signal or the first part of the first RF signal containing the first data, (ii) to obtain information from the DUT that is based on second data received by the DUT in the second RF signal or in the second part of the first RF signal, and (iii) and to determine whether the DUT passed or failed testing based on the information.
